(19) United States
(12) Patent Application Publication
(10) Pub. No.: US 2008/0003715 A1
(43) Pub. Date: Jan. 3, 2008

(54) Tapered die-side bumps

(76) Inventors: Kevin J. Lee, Beaverton, OR (US); Figen T. Akin, Portland, OR (US); Kurt Schultz, Banks, OR (US); Raman Vaidyanathan, Hillsboro, OR (US); Shane A. Nolen, Portland, OR (US); Adwait Telang, Hillsboro, OR (US)

Correspondence Address: INTEL CORPORATION;c/o INTELLEVATE, LLC, P.O. BOX 52050, MINNEAPOLIS, MN, 55402, US

(21) Appl. No.: 11/479,091

(22) Filed: Jun. 30, 2006

(51) Int. Cl. H01L 21/00

(52) U.S. Cl. 438/108

(57) ABSTRACT

Embodiments of the invention include apparatuses and methods relating to die-side bumps having a tapered cross-section. In one embodiment, the tapered die-side bump is electrically coupled to a solder bump on a package substrate.

### TECHNICAL FIELD

Embodiments of the invention relate to microelectronics packaging technology. In particular, embodiments of the invention relate to microelectronic devices having tapered die-side bumps.

### BACKGROUND

After a microelectronic chip or die has been manufactured, it is typically packaged before it is sold. The package provides electrical connection to the chip's internal circuitry, protection from the external environment, and heat dissipation. In one package system, a chip is “flip-chip” connected to a package substrate. In a flip-chip package, electrical leads on the die are distributed on its active surface and the active surface is electrically connected to corresponding leads on a package substrate.

FIGS. 1 through 3 illustrate a prior art method for flip-chip packaging a microelectronic chip or die. In FIG. 1, a portion of a microelectronic die 100 including a conductive bump 140 is illustrated. Microelectronic die 100 includes a substrate 105, a device layer 110, an interconnect region 115, and a land 120. Device layer 110 typically includes a variety of electrical circuit elements, such as transistors, conductors, and resistors, formed in and on a semiconductor substrate material. Interconnect region 115 includes layers of interconnected metal vias and metal lines, which are separated by dielectric materials, that provide electrical connection between the devices of device layer 110 and electrical routing to conductive lands, including land 120. Typically, a dielectric layer 125, a barrier metal 135 and a bump 140 are formed over land 120, with bump 140 providing a structure for electrical connection from die 100 to an external package substrate.

As shown in FIGS. 2 and 3, in a common flip-chip package system, microelectronic die 100 is turned over, or flipped, and bonded to a package substrate 150 such that its active surface, including bumps 140, faces a surface of package substrate 150. Bumps 140 are in alignment with solder bumps or balls 155 on the surface of package substrate 150, and electrical connections are formed between bumps 140 and balls 155 at joints 160. As shown, joints 160 typically include portions of bumps 140 being depressed into the solder bumps. Also illustrated in FIG. 3 is an underfill material 170 that is provided between die 100 and package substrate 150.

In some processes, the underfill material is a capillary underfill material and bumps 140 are copper. In such systems, the underfill material may not adhere well to bumps 140 of die 100. The lack of adhesion between bumps 140 and underfill material 160 may cause numerous difficulties. For example, it may cause cracking of the dielectric material in the interconnect region of die 100, leading to broken interconnects and device failure. Further, lack of adhesion may cause undesirable gaps and cracks in the underfill material itself.

### BRIEF DESCRIPTION OF THE DRAWINGS

The invention is illustrated by way of example and not by way of limitation in the figures of the accompanying drawings, in which the like references indicate similar elements and in which:

FIG. 1 is a cross-sectional illustration of a portion of a prior art microelectronic die, including a substrate, a device layer, an interconnect region, a land, a dielectric layer exposing a portion of the land, and a barrier metal and bump coupled to the land.

FIG. 2 is a cross-sectional illustration of a prior art flip-chip structure, including a die having bumps aligned to a package substrate having solder bumps.

FIG. 3 illustrates the structure of FIG. 2 after attachment of the die and the package substrate, and including an underfill material.

FIG. 4 is a cross-sectional illustration of a portion of a microelectronic die, including a substrate, a device layer, an interconnect region, a land, and a dielectric layer over the land and including an opening that exposes a portion of the land.

FIG. 5 illustrates the structure of FIG. 4 with a seed layer formed over the dielectric layer and the land.

FIG. 6 illustrates the structure of FIG. 5 with a layer including a tapered opening formed over the seed layer.

FIG. 7 illustrates the structure of FIG. 6 with a tapered bump formed in the opening and on the seed layer.

FIG. 8 illustrates the structure of FIG. 7 with the layer removed.

FIG. 9 illustrates the structure of FIG. 8 with exposed portions of the seed layer removed.

FIG. 10 is a cross-sectional illustration of a microelectronic die including tapered bumps aligned to a substrate having solder bumps for flip-chip attachment.

FIG. 11 illustrates the structure of FIG. 10 with the die-side tapered bumps and the solder bumps attached to form electrical connections, and portions of solder wicked over the sidewalls of the tapered bumps.

FIG. 12 illustrates the structure of FIG. 11 with an underfill material between the die and the substrate.

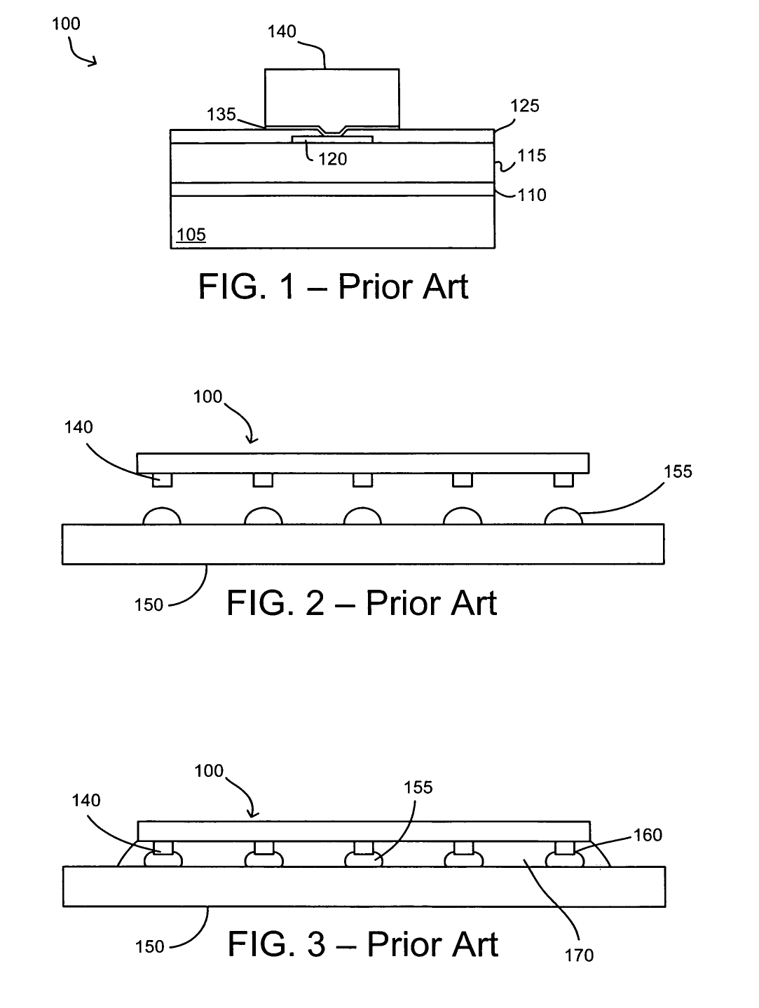

### DETAILED DESCRIPTION

In various embodiments, apparatuses and methods relating to tapered die-side bumps are described. However, various embodiments may be practiced without one or more of the specific details, or with other methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without the specific details described. Furthermore, it is understood that the various embodiments shown in the figures are illustrative representations and are not necessarily drawn to scale.

In flip-chip packaging structures, it is desirable to provide strong adhesion between the underfill material and the electrical connections in the flip-chip package. Such strong adhesion provides enhanced performance and reliability by eliminating or reducing cracks and gaps in the underfill material itself and cracks in the interconnect region of the chip or die. Undesirable cracks could lead to device failure by breaking interconnects or to poor reliability by being a focus point for stresses. Briefly, the present description provides structures and methods that enable enhanced adhesion between the underfill material and the electrical connections by wicking solder material over tapered die-side bumps prior to underfill. The solder material wets the tapered bumps and, since the underfill adheres well to the solder, provides strong adhesion for the connection. Further, the tapered bumps offer the advantage of having a wider die-side base, which limits the stress on the die during packaging.

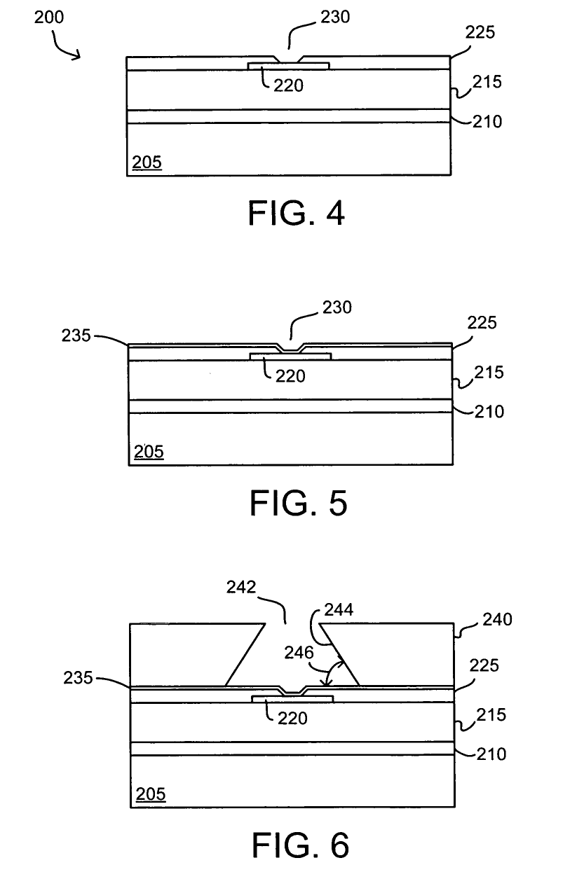

FIGS. 4-12 illustrate methods and structures for a flip-chip package system having tapered bumps and strong adhesion between the underfill material and the electrical connections of the flip-chip package.

FIG. 4 illustrates a portion of a microelectronic die 200 including a substrate 205, a device layer 210, an interconnect region 215, a land 220, and a dielectric layer 225 having an opening 230 exposing a portion of land 220.

In general, the die may be part of a wafer having a plurality of dice or the die may be an individual and separate integrated circuit. Substrate 205 includes any suitable semiconductive material or materials for the formation of operative devices. For example, substrate 205 may include monocrystalline silicon, germanium, gallium arsenide, indium phosphide, or silicon on insulator, or the like. Device layer 210 includes devices formed in and on substrate 205, such as transistors, resistors, or conductors, that form an integrated circuit.

Interconnect region 215 provides electrical interconnection for the devices of device layer 210. Interconnect region 215 includes a stack of metallization layers which include metal lines that are separated and insulated by interlayer dielectric (ILD) materials. The metal lines of the metallization layer are interconnected by conductive vias which are also separated and insulated by dielectric materials. The ILD materials include any suitable insulative materials, including low-k ILD materials, which have a dielectric constant, k, of less than that of silicon dioxide (less than about 4). Low-k ILD materials are advantageous because they reduce the capacitance between adjacent metal lines and thereby improve the performance of the overall microelectronic device, for example by reducing RC delay. However, many low-k ILD materials are relatively brittle and susceptible to cracking or delamination. Therefore, the following methods and structures may enable the use or increase the reliability of some low-k ILD materials by reducing stresses on those materials.

Land 220 is electrically connected to one or more of the metal lines and vias of interconnect region 215 and provides a conductive land or pad for the subsequent formation of an electrical lead or bump. In some examples, land 220 may be considered a part of interconnect region 215, such as a top metallization layer of interconnect region 215. In other examples, land 220 is formed over interconnect region 215. Land 220 includes any suitable conductive material, such as copper or aluminum. Dielectric layer 225 is formed over (as shown) or around land 220 and includes any suitable insulative material, such as a passivation materials or insulative materials. To form dielectric layer 225 having opening 230, a bulk dielectric layer is first formed by a spin-on method or other suitable deposition method. Then, opening 230 is formed in dielectric material 230 by known techniques, such as photolithography and etch techniques.

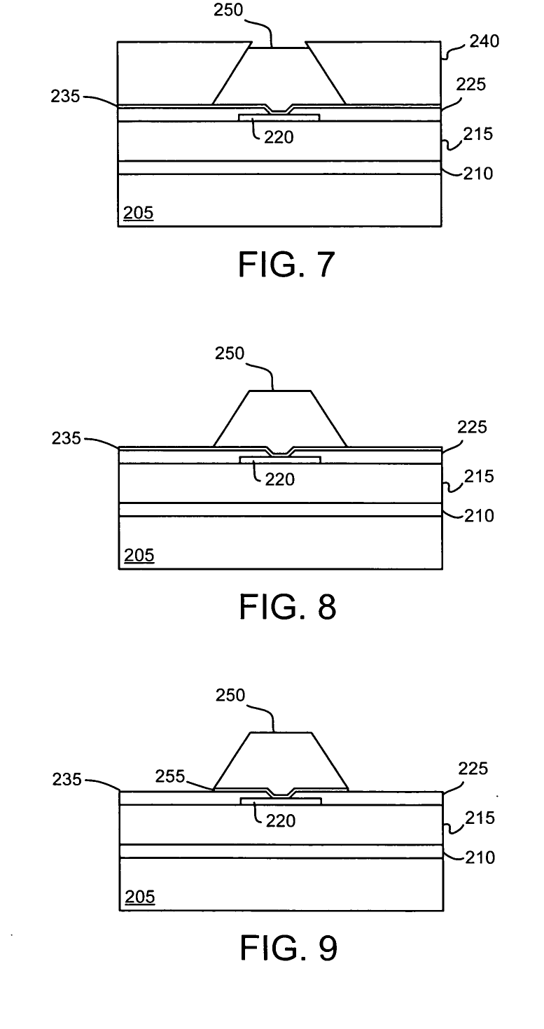

As illustrated in FIG. 5, a seed layer 235 is formed over dielectric layer 225 and the exposed portion of land 220, partially filling opening 230. Seed layer 235 includes any suitable material or stack of materials that provides a suitable seed for the formation of a bulk conductor material, as is discussed in FIG. 7 below. For example, for the formation of a bulk copper conductor, a copper seed layer is used. Prior to the formation of seed layer 235, a barrier or adhesion layer may be provided. The barrier layer may include tantalum and tantalum nitride or titanium and titanium nitride, for example. The barrier layer and the seed layer are formed by known techniques, such as atomic layer deposition (ALD), physical vapor deposition (PVD), and chemical vapor deposition (CVD).

Next, a layer 240 including a tapered opening 242 is formed over seed layer 235, such that the land is exposed, as is illustrated in FIG. 6. Herein, the term “over” refers to the surface that is away from the substrate, such that the substrate is used as the frame of reference and subsequent structures are built “up” upon the substrate. Therefore, use of terms such as bottom, top, over, and side are with reference to the substrate as being toward the bottom of the structure, and not referring to “up” or “down” in reference to the ground or any other frame of reference.

As shown, tapered opening 242 includes sidewalls 244 having an acute angle 246 between sidewalls 244 and the exposed surface. Angle 246 may be any suitable acute angle that provides a tapered bump that promotes adequate solder wicking, as discussed below. In various examples, angle 246 may be in the range of about 25 to 70 degrees. Specific examples include angles in the ranges of about 25 to 35 degrees, 40 to 50 degrees, or 60 to 70 degrees. From a top down view, tapered opening 242 has any suitable shape for defining a conductive bump, such as round, oval, square, or rectangular. Also, as shown, tapered opening 242 has a bottom opening adjacent to seed layer 235 and a top opening away from seed layer 235. The width of the tapered opening at the bottom of the opening is greater than the width of the tapered opening at the top of the opening. The opening is any size that is suitable for a conductive bump. In some examples, the cross-sectional width of the tapered opening at the bottom surface is in the range of about 80 to 120 microns.

Layer 240 includes any suitable material that facilitates the formation of tapered opening 242 and provides sufficient structure for the subsequent formation of a tapered bump, as is discussed below. For example, layer 240 may include a negative photoresist and tapered opening 242 may be formed by photolithography processing. In typical photolithography processing, the process parameters are tuned to form openings having substantially vertical sidewalls. However, by varying those parameters, tapered openings may be formed. Typical photolithography process parameters include exposure intensity and duration, exposure focus conditions, post exposure bake temperature and duration, and develop duration. In one example, the tapered opening is formed by under-exposing (reducing exposure intensity and/or duration) a negative photoresist. In another example, the tapered opening is formed by under-baking (reducing the temperature and/or duration of post-exposure bake) a negative photoresist. In yet another example, the tapered opening is formed by over-developing (reducing develop duration) a negative photoresist. And in another example, the focus conditions are altered (by moving the focus plane of the photolithography equipment from in focus to out of focus) to form the tapered opening. In other examples, any combination of these conditions may be used.

As illustrated in FIG. 7, a tapered bump 250 is then formed within the confines of the opening. Tapered bump 250 includes any suitable conductive material, such as copper, and tapered bump 250 may be formed by any suitable technique. In one example, tapered bump 250 is formed by a timed electroplating method using seed layer 235. Tapered bump 250 substantially takes the form of the opening in layer 240 and may therefore include any of the sidewall angles or shapes discussed above. The sidewalls of the tapered bump therefore extend inwardly continuously from the die surface to the end of the bump opposite the die surface, and the width of the bump at the die surface is greater than the width of the bump at the end of the bump opposite the die surface. In one example, the opening has a round shape as viewed from the top down and tapered bump 250 has the shape of a frustum of a cone (or approximating a frustum—in photolithography processing, a “round” shape may actually include a series of lines which approximate a smooth circular or oval shape due to limitations in mask production).

Layer 240 is then removed, as is shown in FIG. 8. Layer 240 is removed any suitable technique, such as a wet etch process, dry etch process, or a resist strip process. Next, as is illustrated in FIG. 9, the portion of seed layer 235 that is exposed (i.e., not covered by the tapered bump) is removed by any suitable technique. For example, the portion of seed layer 235 may be removed by a wet etch processing step. A wet etch processing step may also remove a small portion of tapered bump 250 if the bump and the seed layer are the same material or if there is little or no etch selectivity between the two materials. Since only a small portion of the bump is removed, there will be little or no adverse effect to the shape of the bump. In order to remove the majority of the seed layer and only a small amount of the bump, a timed wet etch step may be used.

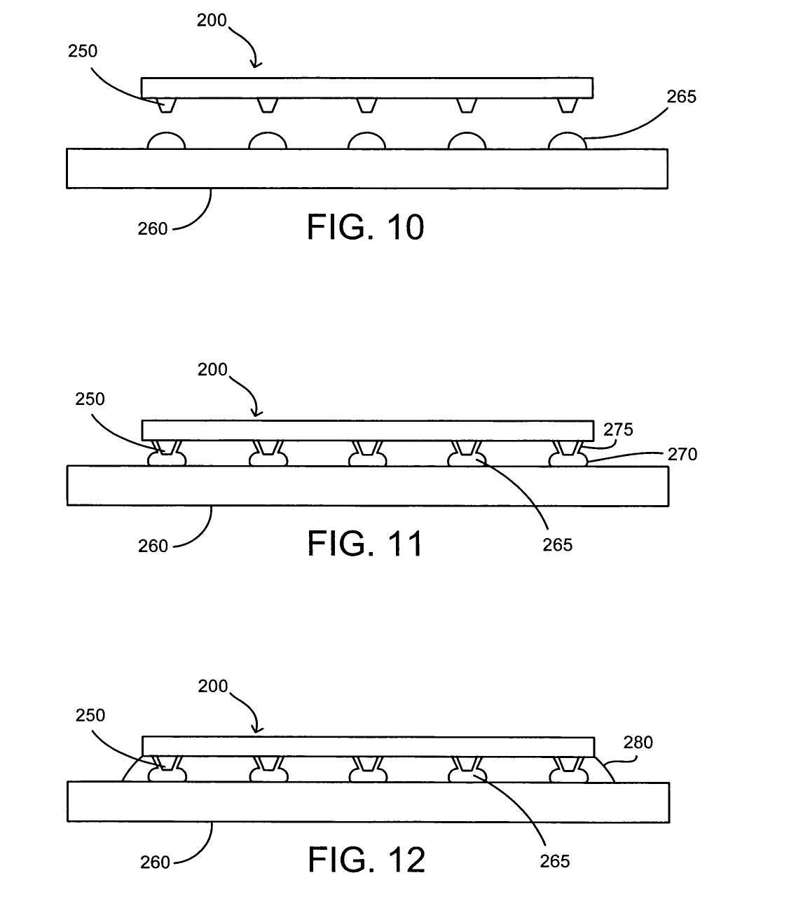

As illustrated in FIGS. 10-12, microelectronic die 200, including tapered bumps 250, may be flip-chip attached to a substrate 260 including solder bumps 265. In FIGS. 10-12, several elements illustrated in FIGS. 4-9 are not illustrated for the sake of clarity. In some examples, bumps 250 are formed at the end of wafer processing on a number of microelectronic dice and the attachment of die 200 to substrate 260 is made after dicing substrate 205 to separate the multiple integrated circuits into discrete die.

Substrate 260 includes any suitable packaging substrate, such as a printed circuit board (PCB), interposer, motherboard, card, or the like. Solder bumps 265 are any suitable solder material, including lead-based solders or lead-free solders. Example lead-free solders include alloys of tin and silver or alloys of tin and indium. Lead free solders may be advantageous due to environmental and health concerns related to the use of lead in consumer products.

As shown in FIG. 10, microelectronic die 200 and substrate 260 are positioned such that tapered bumps 250 and respective solder bumps 265 are substantially aligned, and the die and the substrate are brought together at an elevated temperature such that the solder reflows and, upon cooling, form joints 270 with tapered bumps 250 to electrically couple die 200 and substrate 260, as is shown in FIG. 11. Also illustrated in FIG. 11 are solder portions 275 that coat tapered bumps 250. The coated portions extend beyond the joint between the solder and the die-side bump toward the active surface of the die. In various examples, the solder portions may completely or partially coat tapered bumps 250. Solder portions 275 coat or wet tapered bumps 250 by wicking along the surfaces of tapered bumps 250 while in a molten state during solder joint formation. Tapered bumps 250 cause or enhance the wicking action because of their narrower top surface at the end of the bump adjacent to substrate 260. A narrower surface on the solder side will typically cause more wicking for any given solder volume, and having tapered bumps 250 offers the advantage of both a narrower solder side for increased wetting and a wider base at the die surface to distribute stresses that are inherent in flip chip packaging over a wider area and thereby decreasing the probability of crack formation in die 200. Further, providing a narrower surface on the solder side may allow use of a smaller solder volume while providing the advantages of wetting the tapered bumps. Using less solder may offer the advantages of lower costs and allowing for increased bump density.

Next, as illustrated in FIG. 12, an underfill material 280 is formed between die 200 and substrate 260. In one example, underfill material 280 is provided by a capillary underfill process. As discussed, underfill materials typically do not adhere well to die-side bumps, particularly bumps that are copper. However, underfill materials typically do adhere well to both lead-based and lead-free solder materials. By wicking solder portions along the tapered bumps (or along portions of the tapered bumps), the underfill material adheres more strongly to the electrical connections of the flip-chip package. Due to the stronger adhesion, gaps and cracks in the underfill material are reduced or eliminated. Further, gaps around the electrical connections are also reduced or eliminated, which reduces the tendency for cracks in the die, in particular in the ILD material in the interconnect region of the die. Therefore, tapered bumps coated partially or completely by solder material may enhance the yield and reliability of flip-chip packaged integrated circuits.

Reference throughout this specification to “one embodiment” or “an embodiment” means that a particular feature, structure, material, or characteristic described in connection with the embodiment is included in at least one embodiment of the invention. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments.

It is to be understood that the above description is intended to be illustrative, and not restrictive. Many other embodiments will be apparent to those of ordinary skill in the art upon reviewing the above description. The scope of the invention should, therefore, be determined with reference to the appended claims, along with the full scope of equivalents to which such claims are entitled.

What is claimed is:

1. A method comprising:
forming a microelectronic die having a surface including at least a portion of a conductive land;
forming a layer over the die surface, the layer including a first surface adjacent to the die surface, a second surface opposite the first surface, and a tapered opening, wherein the tapered opening exposes the portion of the conductive land, and wherein the tapered opening has a first width at the first surface of the pattern layer that is greater than a second width at the second surface of the pattern layer;
forming a conductive material in the tapered opening to form a tapered bump; and
removing the pattern layer.

2. The method of claim 1, further comprising:
coupling the tapered bump to a solder bump on a substrate to form a joint, wherein the solder bump material wets at least a portion of the tapered bump beyond the joint.

3. The method of claim 2, further comprising:
forming an underfill material between the surface of the microelectronic die and a surface of the substrate.

4. The method of claim 2, wherein the solder bump comprises at least one of tin, indium, or lead.

5. The method of claim 1, further comprising:
forming a seed layer over the microelectronic die surface before forming the pattern layer, wherein forming the conductive material includes electroplating.

6. The method of claim 1, wherein the conductive material comprises copper.

7. The method of claim 1, wherein the pattern layer comprises a negative photoresist, and forming the pattern layer including the tapered opening includes an under-expose and over-develop photolithography processing to form the tapered opening.

8. The method of claim 1, wherein the tapered bump has a tapered sidewall having an angle between about 40 and 50 degrees.

9. An improved method for forming a flip-chip joint between a microelectronic die and a package substrate comprising:
forming a tapered bump over a surface of the microelectronic die, the tapered bump being wider at the surface of the microelectronic die than at an end of the tapered bump opposite the surface; and
coupling the tapered bump to a solder bump on the package substrate.

10. The method of claim 9, wherein the solder bump material wets at least a portion of the tapered bump beyond the joint.

11. The method of claim 10, further comprising:
forming an underfill material between the surface of the microelectronic die and a surface of the package substrate.

12. The method of claim 10, wherein the solder bump comprises at least one of tin, indium, or lead.

13. An apparatus comprising:
a tapered bump on a surface of a microelectronic die, wherein the tapered bump has a tapered sidewall that extends inwardly from the surface of the microelectronic die to an end of the tapered bump opposite the surface such that an angle between the sidewall of the tapered bump and the surface of the microelectronic die is acute.

14. The apparatus of claim 13, wherein the angle is in the range of about 40 to 50 degrees.

15. The apparatus of claim 13, wherein the tapered bump has the shape of a frustum of a cone.

16. The apparatus of claim 13, wherein the tapered bump comprises copper.

17. The apparatus of claim 13, further comprising:
a solder bump on a substrate surface electrically coupled to the tapered bump at a joint.

18. The apparatus of claim 17, further comprising:
a layer of solder material over at least a portion of the tapered sidewall of the tapered bump and adjacent to the joint.

19. The apparatus of claim 17, wherein the solder bump comprises at least one of tin, indium, or lead.

20. The apparatus of claim 17, further comprising:
an underfill material between the surface of the microelectronic die and the substrate surface.
